(19) United States
(12) Patent Application Publication
(10) Pub. No.: US 2008/0251414 A1
(43) Pub. Date: Oct. 16, 2008

(54) Container and metal actuator of latching mechanism thereof

(75) Inventor: Pao-Yi Lu, Taipei County (TW)

Correspondence Address: SINORICA, LLC, 528 FALLSGROVE DRIVE, ROCKVILLE, MD, 20850, US

(73) Assignee: Gudeng Precision Industrial Co., Ltd.

(21) Appl. No.: 11/979,622

(22) Filed: Nov. 6, 2007

(30) Foreign Application Priority Data
Apr. 13, 2007 (CN) 096205942

(51) Int. Cl. H01L 21/673; B65D 85/90; B65D 55/14; H01L 21/67

(52) U.S. Cl. 206/710; 220/315; 414/217.1; 70/63

(57) ABSTRACT

A container having a box door and a box is disclosed in this invention, which has an internal area within the box for storage; when the box is joined with the box door, the internal area is sealed off from the external environment. A latching mechanism is disposed within the box door and comprises a metal actuator and a latch plate, and the metal actuator and the latch plate are connected. Movements of the metal actuator allow the latch plate to shift positionally, and thus the latch plate is moved from a first position to a second position. When the latch plate is in the first position, the box and the box door may be separated from each other, whereas when the latch plate is in the second position, the box and the box door are inseparable.

### FIELD OF THE INVENTION

The invention relates to amendments of a container, and more particularly to a latching mechanism of a container, which may withstand multiple operations of manufacturing machines and remain free from structural damage.

### DESCRIPTION OF PRIOR ART

As the wafer fabrication technology employed in wafer foundries and semiconductor fabrication plants continually advances, production process more refined than the 90-nm process has been developed, and as the fine line of the production process is reduced in size while the integration of components is enhanced, the number of components that may be made out of a single wafer is increased consequently. However, this also renders the highly integrated semiconductor components less tolerant of contaminants, and even the most miniscule amount of contaminants (minute particles, minute dusts, or organic substances) may give rise to defects in the components and subsequently disable the electrical properties thereof, which lead to loss of components.

Generally, a dust-free environment such as a clean room is provided in semiconductor production processes, so as to prevent semiconductor components from being contaminated from minute particles in the air. Moreover, the semiconductor components must also be prevented from contamination during transportation, and thus a protective container are required in order to protect the semiconductor components from contamination.

In order to minimize the possible damage that may occur to semiconductor components during transportation or storage, many previous attempts had been carried out in order to enhance the structure and latching mechanism of the container, and the ultimate goal is to further enhance the protection of items carried within the containers.

In the system of Standard Mechanical Interface, the pin from the manufacturing machine is inserted into the actuator of a latching mechanism in order to open or close the container. An actuator disclosed in the U.S. Pat. No. 4,995,430 was made of a plastic material, and because the strength of plastic materials is insufficient, the actuator is prone to breakage during the insertion of the pin after many times of use, which in turn disables the latching mechanism and compromise the safety of the items kept in the container.

Therefore, the latching mechanism must be of sufficient strength in order to withstand operations of opening and closing without breaking, and the invention has proposed a latching mechanism of sufficient strength that may withstand multiple rounds of opening and closing.

### SUMMARY OF THE INVENTION

In light of the disadvantage of breakage resulted from long-term usage in the latching mechanism of conventional containers, an enhanced latching mechanism of containers has been proposed in the invention.

A main objective of the invention is to propose a container for safeguarding or transferring items, wherein a latching mechanism thereof may prevent contaminants from entering the container.

Another objective of the invention is to propose a container for safeguarding or transferring items, wherein a latching mechanism thereof may withstand multiple times of usage without breaking or suffering from structural damage.

A further objective of the invention is to propose a container for use with the Standard Mechanical Interface, and may be used in combination with existing specifications of the Standard Mechanical Interface.

A container having a box door and a box is disclosed in this invention, which has an internal area within the box for storage; when the box is joined with the box door, the internal area is sealed off from the external surroundings. A latching mechanism is disposed within the box door and comprises a metal actuator and a latch plate, and the metal actuator and the latch plate are connected together. Movements of the metal actuator allow the latch plate to shift positionally, and thus the latch plate is moved from a first position to a second position. When the latch plate is in the first position, the box and the box door may be separated from each other, whereas when the latch plate is in the second position, the box and the box door are inseparable.

A container having a box door and a box is disclosed in this invention, which may be applied to a system based on the Standard Mechanical Interface (such as wafer containers or photomask pods). The box includes an internal area and at least two contact surfaces; the box door includes a plurality of first openings, and elastic components are disposed on a surface of the box door that comes into contact with the box. When the box and the box door are joined, the internal area is sealed off from the external surroundings. A latching mechanism is disposed within the box door, which comprises a metal actuator and a latch plate; the metal actuator is connected to the latch plate, and movements of the metal actuator allow the latch plate to shift positionally, so that the latch plate may move between a retracted position and an extended position. When the latch plate is at the retracted position, the box and the box door may be separated from each other; when the latch plate is at the extended position, the latch plate juts out of the box door via the first openings. The metal actuator allows the latch plate to move from the extended position to a secured position and press tightly against the contact surfaces of the box, so that the box and the box door are pressed together tightly and made airtight by the elastic components.

Because elastic components are disposed on a surface of the box door that comes into contact with the box in the container of this invention, the box door and the box are sealed when they are joined. A plurality of openings (for example, four openings) are disposed in the box door of the container, a metal actuator and a latch plate are disposed within the box door; the metal actuator is made of a metal material like aluminum alloys or magnesium alloys. The metal actuator includes a plurality of risers and first guiding structures, and the first guiding structure may be a hollow cylinder, which allows a pin from a manufacturing machine to be inserted and drive the metal actuator to rotate, and control the rotating directions of the metal actuator. A first end of the latch plate includes a bow-shaped second guiding structure, and a second end of the latch plate includes a plurality of latch fingers. When the metal actuator is rotated, the second guiding structure moves along with movements of the first guiding structure accordingly, such that the latch fingers also move and become inserted into the first openings of the box door; continuous rotation of a fastening knob makes the risers downwardly press the first end of the latch plate, which in turn raises the second end of the latch plate, so that the latch fingers press against and fasten the box and the box door together.

In addition, a brake apparatus may also be disposed within the box door, which comprises a protruding stopper and a metal elastomer. The stopper is disposed on the box door, and the latch plate cannot move further when it has run into the stopper, which effectively limits the range in which the latch plate may move; the metal elastomer connects the latch plate and the box door, and is used to provide an elastic force that helps push the latch plate when its direction of movement is changed.

### BRIEF DESCRIPTION OF DRAWINGS

The structure and the technical means adopted by the present invention to achieve the above and other objectives can be best understood by referring to the following detailed description of the preferred embodiments and the accompanying diagrams, wherein:

FIG. 1A is a three-dimensional view that shows a box door and a box of a wafer container according to a preferred embodiment of the invention.

FIG. 1B is a three-dimensional view that shows the box door and the box of the wafer container shown in FIG. 1A being assembled together.

FIG. 2 is a schematic view that shows the allocation of a latching mechanism according to a preferred embodiment of the invention.

FIG. 3 is a schematic view that shows a latching mechanism of a container according to a preferred embodiment of the invention.

FIG. 4A is a three-dimensional view that shows a metal actuator according to a preferred embodiment of the invention.

FIG. 4B is a dissected view that shows a cross-section obtained by cutting across the B-B direction shown in FIG. 4A.

FIG. 5 is a schematic view that shows the allocation of a latching mechanism according to another preferred embodiment of the invention.

### DETAILED DESCRIPTION OF PREFERRED EMBODIMENTS

The content of the invention is illustrated by using a container for semiconductors as an example in the preferred embodiments. However, the purpose of the container of the invention is to keep an item clean or sealed, and thus may also be applied to medical equipment, therapeutic equipment, biochemical equipment, or optic instruments.

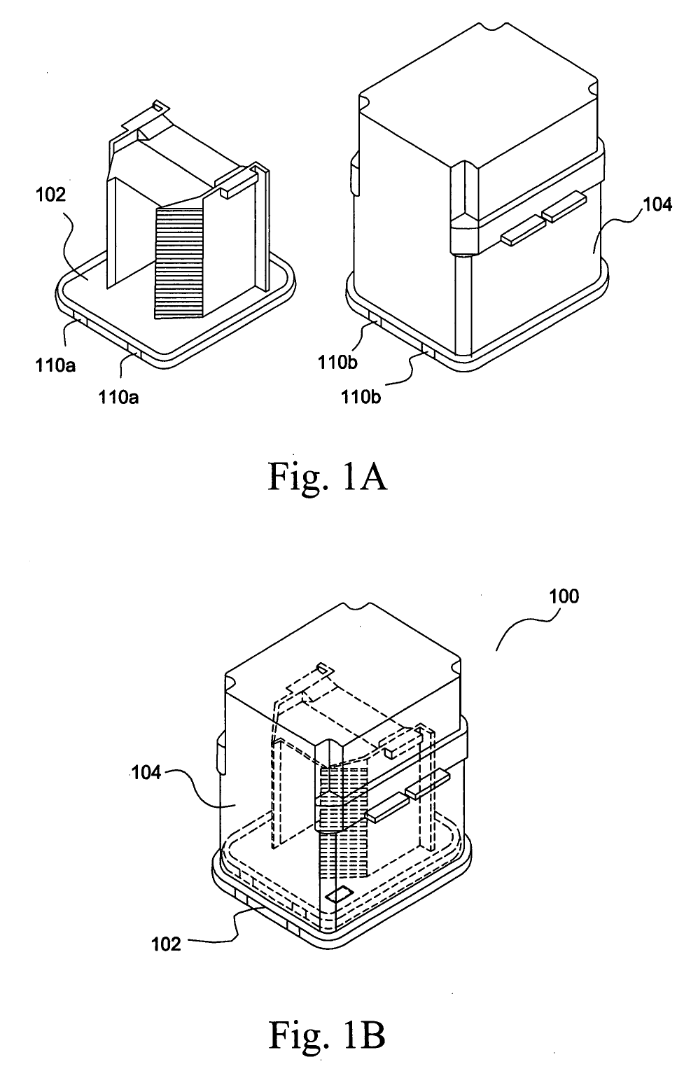

Referring to FIGS. 1A and 1B, which show schematic views of a wafer container 100; the wafer container 100 comprises a box door 102 and a box 104; an elastic components (such as an O-shaped ring, or any elastic materials that do not produce contaminating particles) is disposed on a surface of the box door 102 that comes into contact with the box 104, which is used to keep the box door 102 and the box 104 tightly sealed when the two come into contact. A conductive substrate may be further added to the box door 102, and a metal lining may be added to the inside of the box 104. Both the metal lining and the conductive substrate allow electrical charges to escape, thereby creating a shielding against electrical charges and protecting the guarded items from being damaged by statics.

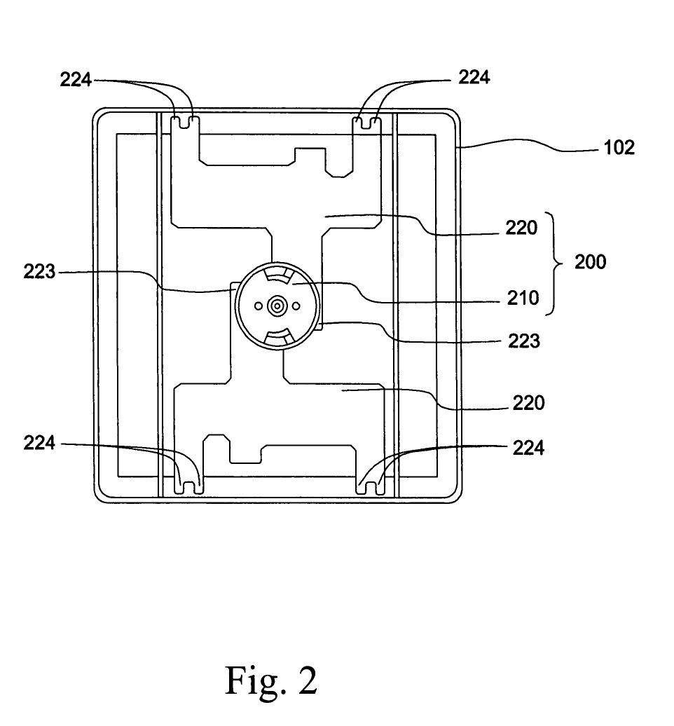

As indicated in FIG. 2, a latching mechanism 200 is disposed within the box door 102, which allows the box door 102 to be joined and fastened with the box 104, so that a plurality of wafers may be safely and stably guarded within the box 104.

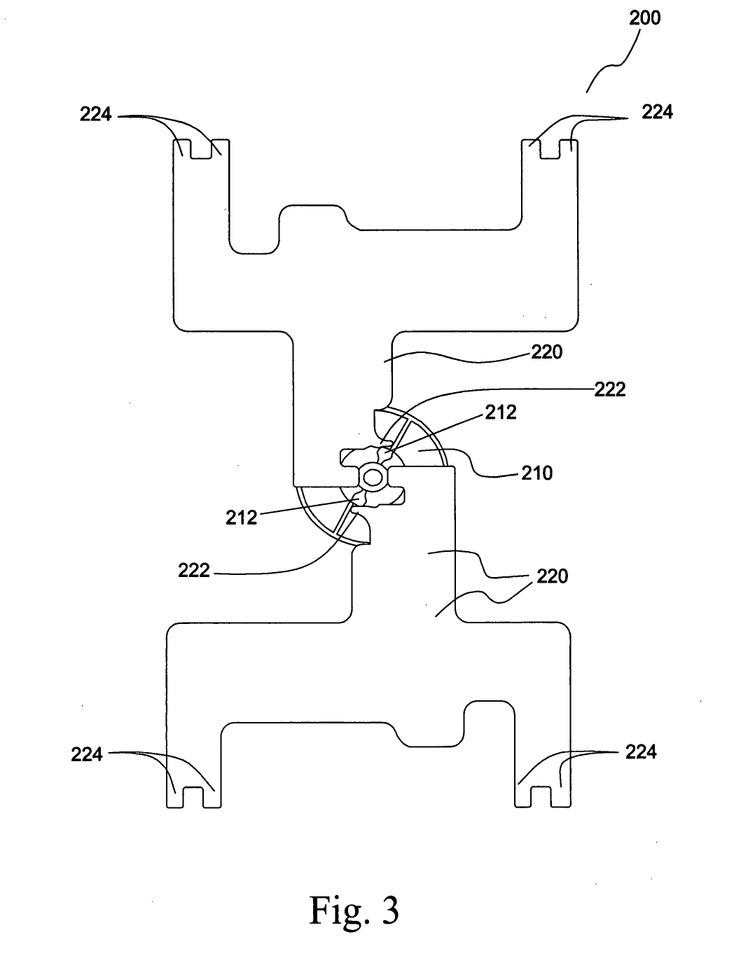

Referring to FIGS. 2 and 3, the latching mechanism 200 comprises a metal actuator 210 and two latch plates 220. The metal actuator 210 may be comprised of aluminum alloys or magnesium alloys, and coated with a polymer material of low volatility thereon, such as poly ether ether ketone compounds or polyimide compounds, which effectively enhances the strength of the metal actuator 210; and the coating of the polymer material also reduces the occurrence of metal particles. The latch plates 220 may be comprised of a polymer material or a metal of better strength, or made up of a metal coated with a polymer material thereon (such as polyether ether ketone compounds or polyimide compounds).

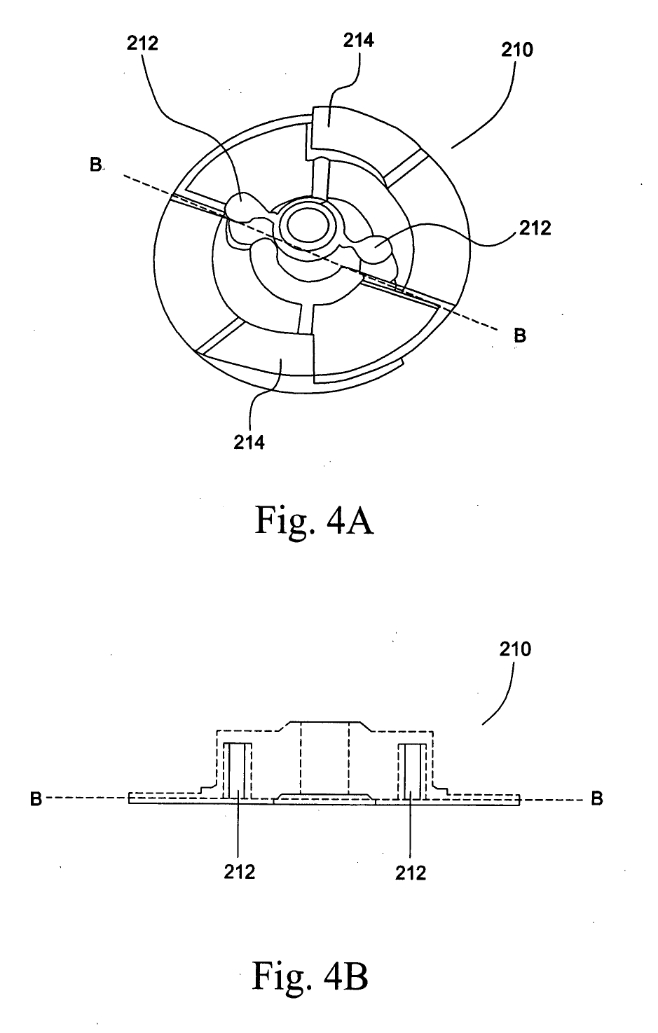

The metal actuator 210 is preferably manufactured as a protruding wheel having risers 214 (shown in FIG. 4A) and first guiding structures 212. The first guiding structures 212 are a pair of protruding hollow cylinder (as indicated in FIG. 4B); when the container is used in combination with a manufacturing machine, the manufacturing machine may insert at least a pin (usually two) into the hollow cylinder of the first guiding structures 212, so as to control rotating directions of the metal actuator 210 and drive a metal fastening knob to rotate. When the metal actuator 210 is rotated, a bow-shaped second guiding structure 222 (shown in FIG. 3) located at a first end 223 of the latch plate 220 is driven to move along with movements of the first guiding structure 212 accordingly, such that the latch plates 220 move outwardly and latch fingers 224 also move and become inserted into the first openings 110a (shown in FIG. 1A) of the box door 102. Continuous rotation of the metal actuator 210 makes the risers 214 downwardly press on the first end 223 of the latch plates 220, which in turn allows a latch finger 224 located on a second end 224 of the latch plates 220 to press against the box 104 of the container 100 and become sealed and airtight. If the aforesaid process is reversed, the joining between the box door 102 and the box 104 is loosened.

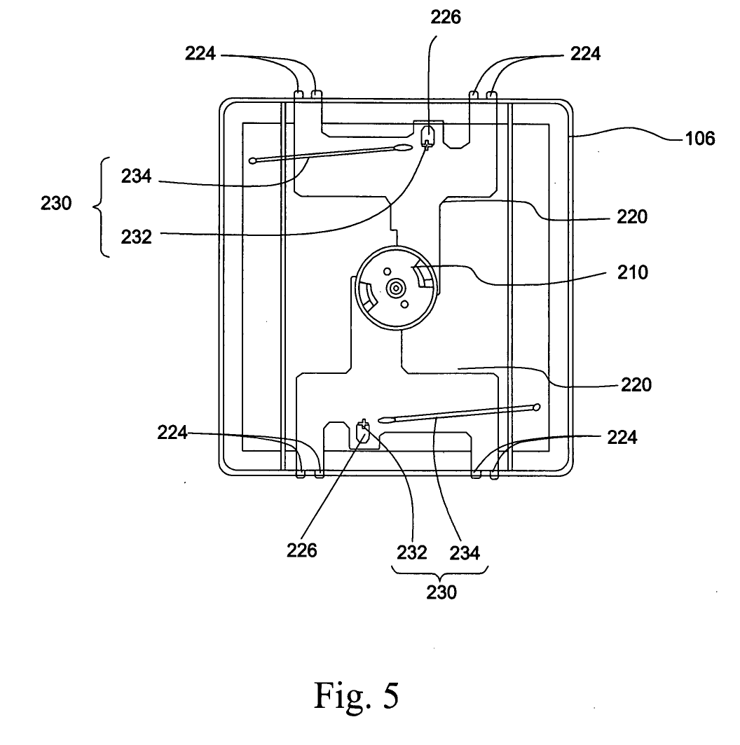

According to another preferred embodiment of the invention, as shown in FIG. 5, a brake apparatus 230 may be further disposed within a box door 106 and fitted with the latch plates 220. The brake apparatus 230 comprises a stopper 232 and a metal elastomer 234; the stopper 232 is disposed in the box door 106 in order to be fitted with an aperture 226 of the latch plates 220. When the latch plates 220 is driven to move, the stopper 232 limits a range in which the latch plates 220 may move; the metal elastomer 234 has an end connected to the latch plates 220 and another end connected to the box door 106; when the direction of movement is changed, the elasticity of the metal elastomer 234 may help the latch plates 220 in retraction thereof.

According to another preferred embodiment of the invention, a brake apparatus may be disposed within the box door. The brake apparatus includes a protruding stopper and a metal elastomer; the stopper is disposed inside of the box door for limiting a range of movement for the latch plates; the metal elastomer connects the latch plates with the box door, and helps change moving directions of the latch plates via elasticity thereof.

The brake apparatus 230 may be disposed within the box door 106 in order to be fitted with the latch plates 220; the brake apparatus 230 comprises a stopper 232 and a metal elastomer 234. The stopper 232 is disposed in the box door 106 in order to be fitted with an aperture 226 of the latch plates 220. When the latch plates 220 is driven to move, the stopper 232 limits a range in which the latch plates 220 may move; the metal elastomer 234 has an end connected to the latch plates 220 and another end connected to the box door 106; when the direction of movement is changed, the elasticity of the metal elastomer 234 may help the latch plates 220 in retraction thereof.

In summary, the latching mechanism in the container of the invention not only allows the container to be securely fastened and sealed, but also eliminates problems existing in conventional containers. In addition, the latching mechanism of the invention has the following advantages: because a metal actuator of decent strength is used in the latching mechanism of the invention, the latching mechanism may withstand multiple operations of inserting and rotating from a pin of a manufacturing machine without breaking, and will not produce dusts or particles, thus further extending the lifespan of the container.

Although preferred embodiments and related drawings of the invention has been described for purposes of illustration, it is understood that the preferred embodiments are merely examples of the invention, and various changes and modifications to the described embodiment can be carried out without departing from the scope and the spirit of the invention as disclosed in the appended claims.

What is claimed is:

1. A container used for safeguarding or transferring items, comprising:
a box having an internal area for storing items;
a box door for separating and isolating the internal area from external surroundings; and
at least one latching mechanism disposed within the box door; the latching mechanism comprises:
at least one actuator; and
at least one latch plate being connected to the actuator;
when the actuator is moved and subsequently allows the latch plate to shift positionally, the latch plate is moved from a first position to a second position; when the latch plate is in the first position, the box and the box door may be separated from each other; whereas when the latch plate is in the second position, the box and the box door are inseparable; the actuator is selected from metal materials.

2. The container described in claim 1, wherein the actuator is coated with a polymer material thereon.

3. The container described in claim 2, wherein the polymer material is selected from polyether ether ketone compounds or polyimide compounds.

4. The container described in claim 1, wherein the latch plate is comprised of a polymer material.

5. The container described in claim 4, wherein the polymer material is selected from polyether ether ketone compounds or polyimide compounds.

6. The container described in claim 1, wherein the latch plate is resulted from coating a polymer material over a metal.

7. The container described in claim 1, wherein the actuator is a protruding wheel.

8. The container described in claim 1, wherein the actuator is comprised of aluminum alloys or magnesium alloys.

9. The container described in claim 1, wherein the container is used in the Standard Mechanical Interface System.

10. The container described in claim 1, wherein the container is a wafer container or a photomask pod.

11. The container described in claim 1, wherein an elastic structure is disposed on a surface of the box door that comes into contact with the box.

12. A container used for safeguarding or transferring items, comprising:
a box having an internal area for storing items, and at least two contact surfaces;
a box door for separating and isolating the internal area from external surroundings, and a plurality of first openings being disposed on a perimeter thereof;
at least two latch plates being disposed within the box door and movable between a retracted position and an extended position; when the latch plates are at the retracted position, the latch plates may be completely enclosed within the box; when the latch plates are at the extended position, the latch plates may jut out of the box via the first openings; and
at least a metal actuator for allowing the latch plates to move back and forth between the retracted position and the extended position, so that the latch plates may move from the extended position to a secured position and press tightly against the contact surfaces, thereby allowing the box door and the box to be combined and sealed.

13. The container described in claim 12, wherein the latch plates are comprised of metal.

14. The container described in claim 12, wherein the latch plates are comprised of aluminum alloys or magnesium alloys.

15. A container used for safeguarding or transferring items, comprising:
a box having an internal area for storing items;
a box door for separating and isolating the internal area from external surroundings, and a plurality of first openings being disposed on a perimeter thereof; and
at least one latching mechanism disposed within the box door; the latching mechanism comprises:
at least one metal actuator being disposed inside of the box door and having a plurality of risers and first guiding structures; and
a plurality of sliders, each of which has a second guiding structure disposed at a first end thereof and a plurality of latch fingers disposed at a second end thereof;
wherein when the metal actuator is rotated, the second guiding structure moves along with movements of the first guiding structure accordingly, such that the latch fingers also move and become inserted into the first openings;
continuous rotation of the metal actuator makes the risers downwardly press the first end of the sliders, which in turn raises the second end of the sliders, so that the latch fingers press against and fasten the box of the container.

16. The container described in claim 15, wherein the risers of the metal actuator are slopes, as a height of the slopes changes due to rotation, downward pressing from the first ends of the sliders changes accordingly.

17. The container described in claim 15, wherein the first guiding structures are protruding hollow cylinders; when the container is used in combination with a manufacturing machine, the manufacturing machine may insert at least a pin into the hollow cylinder of the first guiding structures, so as to control rotating directions of the first guiding structures.

18. The container described in claim 15, wherein the second guiding structures are bow-shaped structures formed at an edge of the sliders.

19. The container described in claim 15, wherein a metal lining is disposed on a surface of the box facing toward the internal area.

20. The container described in claim 15, wherein a conductive substrate is disposed on a surface of the box door that comes into contact with the internal area.

21. A container used for safeguarding or transferring items, comprising:
a box having an internal area for storing items;
a box door for separating and isolating the internal area from external surroundings, and a plurality of first openings being disposed on a perimeter thereof; and
at least one latching mechanism disposed within the box door; the latching mechanism comprises:
at least one metal actuator being disposed inside of the box door and having a plurality of risers and first guiding structures;
a plurality of sliders, each of which has a second guiding structure disposed at a first end thereof and a plurality of latch fingers disposed at a second end thereof; and
a plurality of brake apparatuses disposed inside of the box door, and may be fitted with the sliders;
wherein when the metal actuator is rotated, the second guiding structure moves along with movements of the first guiding structure accordingly, such that the latch fingers also move and become fitted with the brake apparatuses, as well as becoming inserted into the first openings; continuous rotation of the metal actuator makes the risers downwardly press the first end of the sliders, which in turn raises the second end of the sliders, so that the latch fingers press against and fasten the box and the box door of the container.

22. The container described in claim 21, wherein each of the brake apparatuses includes a stopper and a metal elastomer; the stopper is disposed inside of the box door for limiting a range of horizontal movement of the sliders; the metal elastomer connects the sliders with the box door and helps change directions of the movement.

23. A metal actuator of a latching mechanism for fastening and securing a container for safeguarding or transferring items; the container comprises a box and a box door; the metal actuator comprising:
at least a first guiding structure that is a hollow cylinder, when the metal actuator is used in combination with a manufacturing machine, the manufacturing machine may insert at least a pin into the hollow cylinder of the first guiding structure, so as to drive the actuator to rotate; and
at least a second guiding structure, when the metal actuator is driven via the first guiding structure, the second guiding structure may drive the latch plates combined thereof and achieve the purpose of fastening.
